(19) United States
(12) Patent Application Publication
(10) Pub. No.: US 2015/0059979 A1
(43) Pub. Date: Mar. 5, 2015

(54) PLASMA PROCESSING APPARATUS FOR VAPOR PHASE ETCHING AND CLEANING

(71) Applicant: Gen Co., Ltd., Gyeonggi-Do (KR)

(72) Inventors: Gyoo Dong KIM, Gyeonggi-Do (KR); Sung Yong KANG, Gyeonggi-Do (KR); Woo Gon SHIN, Seoul (KR)

(73) Assignee: Gen Co., Ltd., Gyeonggi-Do (KR)

(21) Appl. No.: 14/164,936

(22) Filed: Jan. 27, 2014

(30) Foreign Application Priority Data
Aug. 28, 2013 (KR) 10-2013-0102625

(51) Int. Cl. H01J 37/32

(52) U.S. Cl. CPC H01J 37/32633; H01J 37/3244; H01J 37/32577; H01J 37/32522; H01J 2237/327; H01J 2237/334; H01J 2237/335
USPC 156/345.33

(57) ABSTRACT

A plasma apparatus for vapor phase etching and cleaning, includes a reactor body configured to process a substrate; a direct plasma generation area in the reactor body, into which a process gas is introduced and in which plasma is directly induced to disassociate the process gas; a substrate processing area in the reactor body in which the substrate is processed by reactive species produced by reacting the disassociated process gas introduced from the direct plasma generation area with a vaporised gas introduced from the outside of the reactor body; a plasma induction assembly configured to induce plasma in the direct plasma generation area; and a gas distribution baffle, disposed between the direct plasma generation area and the substrate processing area, having a plurality of through holes through which the disassociated process gas is introduced from the direct plasma generation area to the substrate processing area.

### CROSS-REFERENCE TO RELATED APPLICATIONS

The present application claims priority of Korean Patent Application No. 10-2013-0102625, filed on Aug. 28, 2013, which is incorporated herein by reference in its entirety.

### FIELD OF THE INVENTION

The present invention relates to a plasma processing apparatus for vapor phase etching and cleaning, and more specifically, to a plasma processing apparatus for vapor phase etching and cleaning, capable of selectively cleaning a surface of a substrate to be processed by causing a direct reaction between a thin film of the surface of the substrate to be processed and high reactive atoms or molecules.

### BACKGROUND OF THE INVENTION

A semiconductor device is an active electronic device having functions of storing, amplifying and switching electrical signals, which is a core part that guides high added values of system and service industries and leads digital information era based on high integration, high performance and low power consumption.

The semiconductor manufacturing process can be generally divided into a pre-process (wafer processing process) and a post-process (assembly process and test process), and the market share of pre-process equipments is about 75%. The market share of a wet cleaning apparatus and an apparatus of dry etching called plasma etching is totally 22.6%, forming the second largest market. In the semiconductor manufacturing process, circuits electrically connecting parts are manufactured as one pattern (circuit design) and then drawn on thin films of a plurality of layers in the semiconductor. At this case, an etching process is to remove unnecessary portions on the substrate (wafer) on which the thin films are formed, thereby exposing the circuit pattern. The etching process is divided into a dry etching process that uses plasma and a wet etching process that uses a cleaning solution.

The dry etching process is a process in which physical and chemical etching is performed by vertical incident particles of ion flux caused by plasma. Accordingly, as the device design becomes smaller and smaller, there occurs a problem in that the pattern is damaged depending on processes. The wet process is a technology that has been commonly used for a long time, wherein unnecessary portions on the wafer surface are removed by dipping the wafer into a container filled with a cleaning solution or spraying the cleaning solution on the wafer surface while rotating the wafer at a predetermined speed. However, the wet process also has a drawback that there occurs a huge amount of waste water and it is difficult to control the amount of cleaning solution and cleaning uniformity. Further, in case of anisotropic etching, the pattern after cleaning may be larger or smaller compared with the intended design, so that it becomes difficult to process fine patterns.

Recently, the size of unit device of the semiconductor chip becomes smaller and smaller as demands for high-speed devices and large-capacity memory devices are increased. Accordingly, the pattern gap formed on the wafer surface becomes narrower and narrower and the thickness of gate insulating film of a device becomes thinner and thinner. Therefore, some problems are emerging, which did not occur in the conventional semiconductor process or were not important. Among them, a typical problem caused by plasma is plasma damage. The plasma damage affects, in property and reliability, devices including transistor in all processes in which the wafer surface is exposed as the semiconductor device becomes miniaturized. Film damage by the electric charge caused by plasma normally occurs in the etching process. The plasma damage is a problem occurring in the dry etching process or the wet etching process, thereby requiring efforts to solve it.

### SUMMARY OF THE INVENTION

In view of the above, the present invention provides a plasma apparatus for vapor phase etching and cleaning, capable of cleaning a substrate surface by causing a direct reaction on a thin film of the surface of the substrate to be processed, whereby there is no plasma damage.

According to an aspect of the present invention, there is provided a plasma processing apparatus for vapor phase etching and cleaning, including a reactor body configured to process a substrate to be processed; a direct plasma generation area in the reactor body, info which a process gas is introduced and in which plasma is directly induced to disassociate the process gas; a substrate processing area in the reactor body in which the substrate to be processed is processed by reactive species produced by reacting the disassociated process gas introduced from the direct plasma generation area with a vaporized gas introduced from the outside of the reactor body; a plasma induction assembly configured to induce plasma in the direct plasma generation area; and a gas distribution baffle, which is disposed between the direct plasma generation area and the substrate processing area and has a plurality of through holes that are perforated, through which the disassociated process gas is introduced from the direct plasma generation area to the substrate processing area.

Further, the gas distribution baffle may include a plurality of vaporized gas injection holes to inject vaporized gas introduced from the outside to the substrate processing area.

Further, the plasma apparatus for vapor phase etching and cleaning according to the present invention may further include one or more gas injection nozzles, each of which directly injects the vaporised gas to the substrate processing area.

Further, the plasma induction assembly may include a first electrode and a second electrode that are capacitively coupled with each other.

Further, the plasma induction assembly may include a dielectric window that is mounted between the first and second electrodes and the direct plasma generation area.

Further, the gas distribution baffle may include a heater to control temperature.

Further, the plasma induction assembly may include a cooling channel.

Further, the vaporized gas may be vaporized H₂O.

According to another aspect of the present invention, there is provided a plasma processing apparatus for vapor phase etching and cleaning, including a reactor body configured to process a substrate to be processed; a direct plasma generation area in the reactor body, into which a process gas is introduced and in which plasma is directly induced to disassociate the process gas; a reactive area in the reactor body, in which a disassociated process gas introduced from the direct plasma generation area is reacted with a vaporized gas introduced from the outside of the reactor body, thereby forming reactive species; a substrate processing area in the reactor body, in which the substrate to be processed is processed by the reactive species introduced front the reactive area; a plasma induction assembly configured to induce plasma into the direct plasma generation area; a first gas distribution baffle that is disposed between the reactive area and the substrate processing area and that includes a plurality of first through holes that are perforated, through which the reactive species is introduced from the reactive area info the substrate processing area; and a second gas distribution baffle that is disposed between the direct plasma generation area and the reactive area and that includes a second gas distribution baffle having a plurality of second through holes, through which the disassociated process gas is introduced from the direct plasma generation area into the reactive area.

Further, the first gas distribution baffle may include a plurality of vaporized gas injection holes to inject the vaporized gas introduced from the outside to the reactive area.

Further, the plasma processing apparatus for vapor etching and cleaning according to another aspect of the present invention may further include one or more gas injection nozzles, each of which directly injects the vaporised gas to the reactive area.

Further, the plasma induction assembly may include first and second electrodes that are capacitively coupled with each other.

Further, the plasma induction assembly may include a dielectric window that is mounted between the first and second electrodes and the direct plasma generation area.

Further, the first gas distribution baffle may include a heater to control temperature.

Further, the plasma induction assembly may include a cooling channel.

Further, the vaporized gas may be vaporized H₂O.

### EFFECTS OF THE INVENTION

The plasma apparatus for vapor etching and cleaning may clean the substrate to be processed without any plasma damage. Further, it has advantages that there does not occur any residual product and the selectivity is high. Furthermore, the surface of the substrate to be processed may be uniformly cleaned by providing the substrate to be process with the gasified gas for the vapor phase cleaning. The temperature of the gasified gas may be controlled using the heater disposed in the has distribution baffle to inject the gasified gas. Furthermore, the substrate to be processed may be cleaned even in the micro-pattern processing process since there is no plasma damage.

### BRIEF DESCRIPTION OF THE DRAWINGS

The above and other objects and features of the present invention will become apparent from the following description of embodiments given in conjunction with the accompanying drawings, in which:

FIG. 1 is a view illustrating a plasma processing apparatus in accordance with a preferred embodiment of the present invention.

FIG. 2 is a view illustrating a simplified structure of a capacitively coupled electrode assembly shown in FIG. 1.

FIG. 3 is a plane view illustrating the top of a first gas distribution baffle shown in FIG. 1.

FIG. 4 is a plane view illustrating the bottom of a first gas distribution baffle shown in FIG. 1.

FIG. 5 is a view illustrating a plasma processing apparatus having a cooling channel in a ground electrode.

FIG. 6 is a view illustrating another embodiment of a first gas distribution baffle.

FIG. 7 is a view illustrating another embodiment of an exhaust baffle.

### DETAILED DESCRIPTION OF THE EMBODIMENTS

Hereinafter, embodiments of the present invention will be described in detail with reference to the accompanying drawings so that the present invention can be readily understood by those stilled in the art. The embodiments of the present invention may be modified in a variety of forms and the scope of the present invention should not be construed to be limited to the embodiments described below. The embodiments of the present invention are provided to fully describe them for those skilled in the art. Accordingly, shapes of elements and the like in the drawings may be exaggerated to emphasize a clear explanation. It is noted that the same parts may be identified by the same reference numeral in each drawing. Also, description of well-known functions and constructions are omitted for clarify and conciseness.

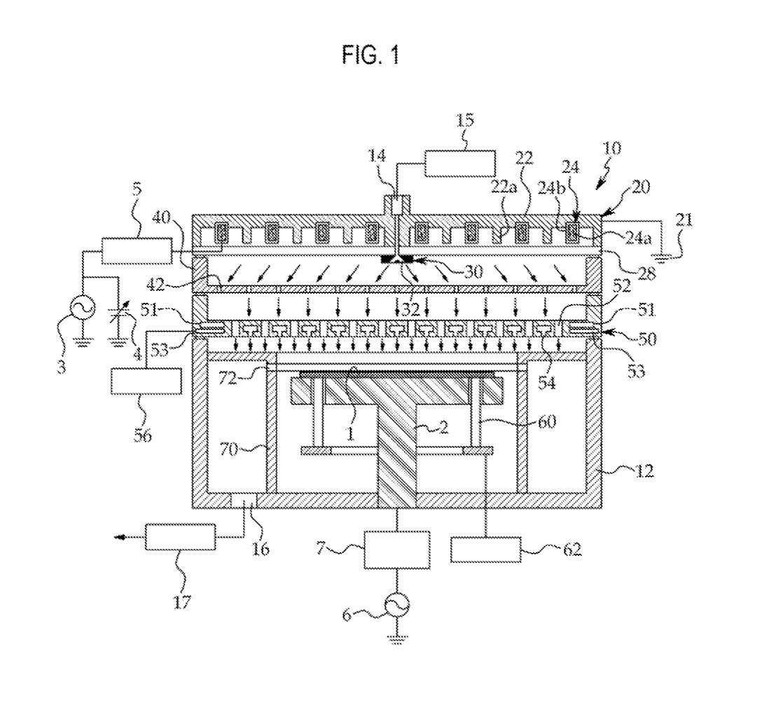

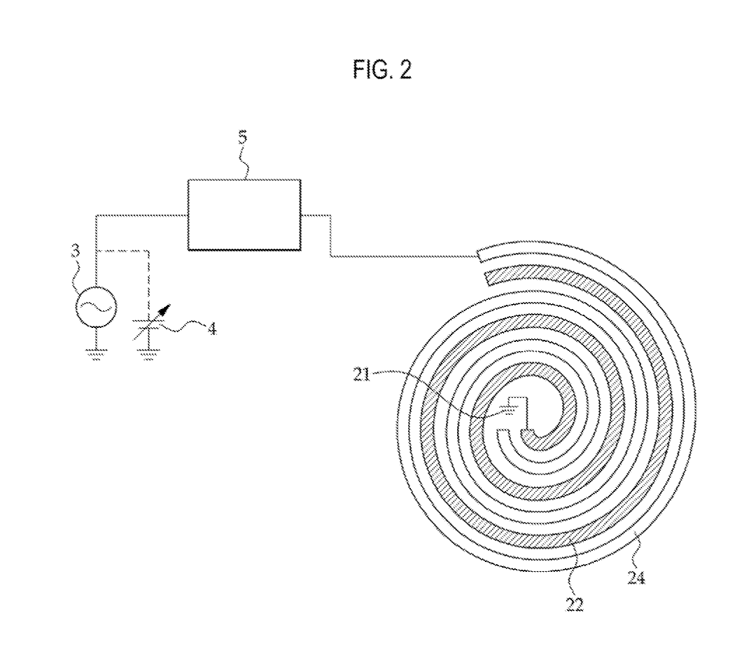

FIG. 1 is a view illustrating a plasma processing apparatus in accordance with a preferred embodiment of the present invention and FIG. 2 is a view illustrating a simplified structure of a capacitively coupled electrode assembly shown in FIG. 1.

Referring to FIG. 1, a plasma processing apparatus 10 is comprised of a reactor body 12, a capacitively coupled electrode assembly 20, a first gas distribution baffle 50, a second gas distribution baffle 40 and a power supply 3. The reactor body 12 includes a substrate support 2 in which a substrate to be processed 1 is disposed. The reactor body 12 has a gas inlet 14 through which a process gas for plasma processing is supplied, on the top of the reactor body 12, and the process gas supplied from a process gas supply 15 is supplied into the reactor body 12 through the gas inlet 14. The gas inlet 14 has a gas injection head 30 including a plurality of gas injection holes 32 through which process gas may be supplied into the reactor body 12. The gas injection head 30 is connected to the gas inlet 14 so that the process gas is injected below a dielectric window 28. The reactor body 12 has a gas outlet 16 formed on the bottom of the reactor body 12, the gas outlet 16 being connected to an exhaust pump 17. The gas outlet 16 is formed at one side of the bottom of the reactor body 12 so that it is not easy for the exhaust gas to be uniformly discharged to the outside of the reactor body 12. Accordingly, an exhaust ring 70 having an exhaust hole 72 is formed in the lower portion of the reactor body 12. The exhaust ring 70 is formed to enclose the vicinity of the substrate support 2, which has a shape having a through hole in the center of it and having an upper portion extended externally. The substrate support 2 is disposed at the through hole in the center of the exhaust ring 70, and the extended portion of the upper portion is mounted, to contact with a side wail of the internal portion of the reactor body 12. Here, the circumference of the exhaust ring 70 has the exhaust hole 72 to uniformly discharge the exhaust gas existing in the reactor body 12. The exhaust hole 72 may have a continuously open shape or be formed of a plurality of through holes.

The reactor body 12 may be manufactured of metal material such as aluminum, stainless steel and copper. Further, it may be manufactured of metal coating, for example, anode processed aluminum or nickel plated aluminum. Further, it may be manufactured of refractory metal. As another alternative, it may be possible to totally or partially manufacture the reactor body 12 of electrically insulating material such as quartz and ceramic. As such, the reactor body 12 may be manufactured of any material suitable to perform an intended plasma process. The reactor body 12 may have structures depending on the substrate to be processed 1 and suitable 1c generate a uniform plasma, for example, circle structure, square structure and any other structures.

The substrate to be processed 1 may be a wafer substrate, a glass substrate and a plastic substrate that are intended to manufacture a variety of apparatus such as a semiconductor device, a display apparatus and a solar cell. The substrate support 2 may be connected to a bias power supply 6, thereby being biased. Further, two bias power supplies that supply radio-frequency powers different each other are electrically connected to the substrate support 2 through an impedance matcher 7, thereby biasing the substrate support 2. Further, the substrate support 2 may be modified and embodied in a structure having zero potential without being supplied with the bias power. The substrate support 2 has lift pins 60 connected to a lift pin driver 62, the lift pins 60 being used to move the substrate to be processed 1 up and down while supporting the substrate to be processed 1. The substrate support 2 may have a heater. Further, the substrate support 2 may have an electrostatic chuck. A vacuum chuck is used to keep the substrate to be processed at a constant temperature in the process. Here, the reactor body 12 has a vacuum state therein, thereby causing a limitation of pressure to occur. However, the electrostatic chuck may be used regardless of the limitation of pressure.

The capacitively coupled electrode assembly 20 is mounted on the top of the reactor body 12 to form a ceiling of the reactor body 12. The capacitively coupled electrode assembly 20 is comprised of a first electrode 22 connected to a ground 21 and a second electrode 24 connected to the power supply 3 to be supplied with a frequency power. The first electrode 22 forms a ceiling of the reactor body 12, which is connected to the ground 21. The first electrode 22 is formed in a plate shape, and has protrusions 22a that are separate one from another at a predetermined gap and formed to be projected to the inside of the reactor body 12. The first electrode 22 has a gas inlet 14 in the center of it. The second electrode 24 is mounted, between the protrusions 22a, which is separated from the first electrode 22 at a predetermined gap. The second electrode 24 is partially inserted into the first electrode 22, thereby being mounted therein. The second electrode 24 is comprised of a power supply electrode 24a connected to the power supply 3 so as to be supplied with a radio frequency power and an insulator 24b formed to cover the power supply electrode 24a externally. The first and second electrodes 22 and 24 directly generate capacitively coupled plasma into the plasma generation area. While the capacitively coupled electrode assembly 20 is used to induce plasma in the present invention, a radio frequency antenna may also be used in a construction to generate inductively coupled plasma.

Referring to FIG. 2, the capacitively coupled electrode assembly 20 has the first electrode 22 connected to a ground and the second electrode 24 connected to the power supply 3, each being helically formed. The protrusion 22a of the first electrode 22 and the power supply electrode 24a of the second electrode 24 are separated with each other at a predetermined gap, each being formed in a helical shape. The second electrode 24 and the protrusion 22a of the first electrode 22 face each other keeping a constant gap therebetween, so that it may be possible to generate uniform, plasma. The capacitively coupled electrode assembly 20 and the second gas distribution baffle 40 have a dielectric window 28 therebetween. The dielectric window 28 is resistant to plasma damage and may be used semipermanently. Here, the first and second electrodes 22 and 24 may also be arranged in parallel.

Referring to FIG. 1 again, the power supply 3 is connected to the second electrode 24 through the impedance matcher 5, supplying a radio-frequency power. The second electrode 24 may be selectively connected to a direct current power supply 4. The first gas distribution baffle 50 is a constituent to distribute the vaporized gas to the substrate to be processed 1, which is disposed over the substrate support 2. The first gas distribution baffle 50 is comprised of a plurality of first through holes 52 each formed therethrough and a plurality of vaporized gas injection holes 54 formed in the vaporized gas supply route 53 which is disposed inside the first gas distribution baffle 50. The plasma generated in an area where direct plasma is generated is distributed to an area where the substrate to be processed 1 is processed, that is, under the first gas distribution baffle 50, through the first through hole 52. The vaporized gas injection hole 54 is formed in the bottom of the first gas distribution baffle 50, that is, formed toward the substrate to be processed 1. The first gas distribution baffle 50 has a vaporized gas supply route 53 used to transfer the vaporized gas therethrough, and the vaporized gas supply route 53 has a plurality of vaporized gas injection holes 54. The vaporized gas may be directly supplied to a space between the first gas distribution baffle 50 and the substrate support 2 from the vaporized gas supply 56 through a plurality of gas injection nozzles, or may be supplied to the space through the vaporized gas injection hole 54 of the vaporized gas supply route 53. The plasma and vaporized gas react in an area under the first gas distribution baffle 50 to process the substrate to be processed 1. The first through hole 52 and vaporized gas injection hole 54 may be formed alternately.

The reactor body 12 may further include a second bas distribution baffle 40 to uniformly distribute the plasma. The second gas distribution baffle 40 is disposed between the capacitively coupled electrode assembly 20 and the first gas distribution baffle 50, which uniformly distributes the plasma through a plurality of second through holes 42 each formed therethrough. The plasma is uniformly distributed through the second gas distribution baffle 40, and then uniformly distributed through the first gas distribution baffle 50 again. The plasma distributed through the first gas distribution baffle 50 reacts with the vaporized gas injected through the vaporized gas injection hole 54 to form reactive species, and the reactive species are absorbed onto the residual product of the substrate to be processed 1 and then removed in the thermal process. Such cleaning method is called vapor phase etching and cleaning. The vapor phase cleaning is a cleaning method having both merits of wet cleaning and dry etching, which causes a direct reaction between a thin film of the surface of the substrate to be processed 1 and atoms or molecules having high reactivity in a low temperature vacuum chamber, thereby generating selective etching and cleaning. The vapor phase cleaning has merits that its selectivity is high, the amount of cleaning is easily controlled, and there is no plasma damage. Further, the vapor phase cleaning has further merit that it normally does not produce residual products and the residual products may be removed using a simple method compared with that of the wet cleaning, although they are produced. The gas to form the reactive species may be vaporised water (H₂O).

The first gas distribution baffle 50 may further have a heater 51 in its border portion. The heater 51 continues to supply heat to the vaporized water H₂O passing through the vaporised gas supply route 53 of the first gas distribution baffle 50 so that the vaporized water H₂O reaches the substrate to be processed 1 in a vapor state without being liquefied. Further, the first gas distribution baffle 50 may further have a sensor to measure a temperature of the vaporized gas.

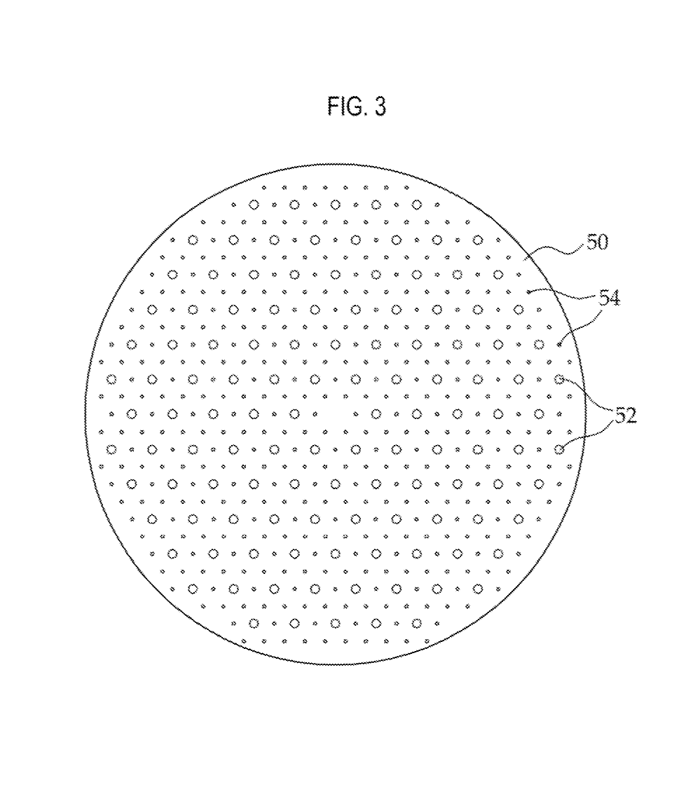

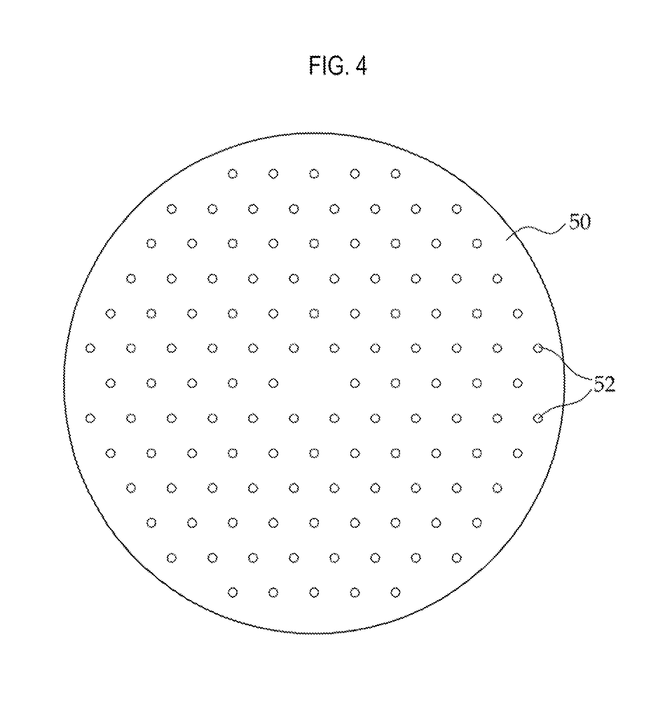

FIG. 3 is a plane view illustrating a top of a first gas distribution baffle shown in FIG. 1 and FIG. 4 is a plane view illustrating a bottom of a first gas distribution baffle shown in FIG. 1.

Referring to FIGS. 3 and 4, the first through hole 52 of the first gas distribution baffle 50 is formed through the first gas distribution baffle 50. On the contrary, the vaporised gas injection hole 54 is formed in a lower portion of the vaporised gas supply route 53 formed inside the first gas distribution baffle 50, that is, is formed on the bottom of the first gas distribution baffle 50. Therefore, the first through hole 52 and the vaporized gas injection hole 54 may be identified on the bottom of the first gas distribution baffle 50, and the first through hole 52 may be identified on the top of the first gas distribution baffle 50. The first through hole 52 is formed larger than the vaporized gas injection hole 54 in an embodiment of the present invention. The vaporized gas injection hole 54 and the first through hole 52 are uniformly formed throughout the first gas distribution baffle 50, so that it may be possible to uniformly distribute the plasma and to uniformly inject the vaporized gas.

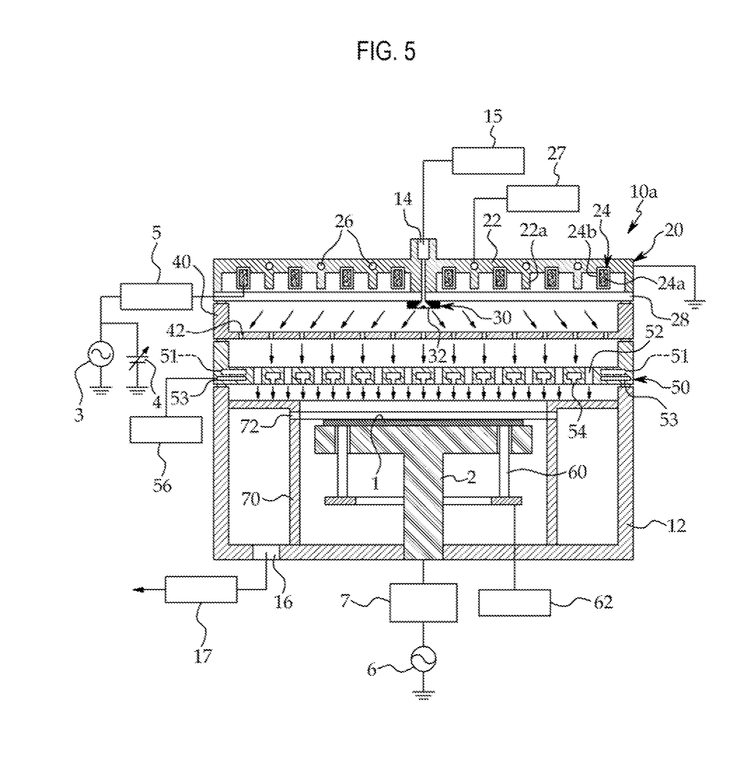

FIG. 5 is a view illustrating a plasma processing apparatus having a cooling channel in a ground electrode.

Referring to FIG. 5, a plasma processing apparatus 10a may include a cooling channel 26 inside a first electrode 22 connected to a ground 21. The cooling channel 26 may be supplied with a cooling water from a cooling water supply 27 to lower the temperature of an overheated first electrode 22, keeping if at a constant temperature.

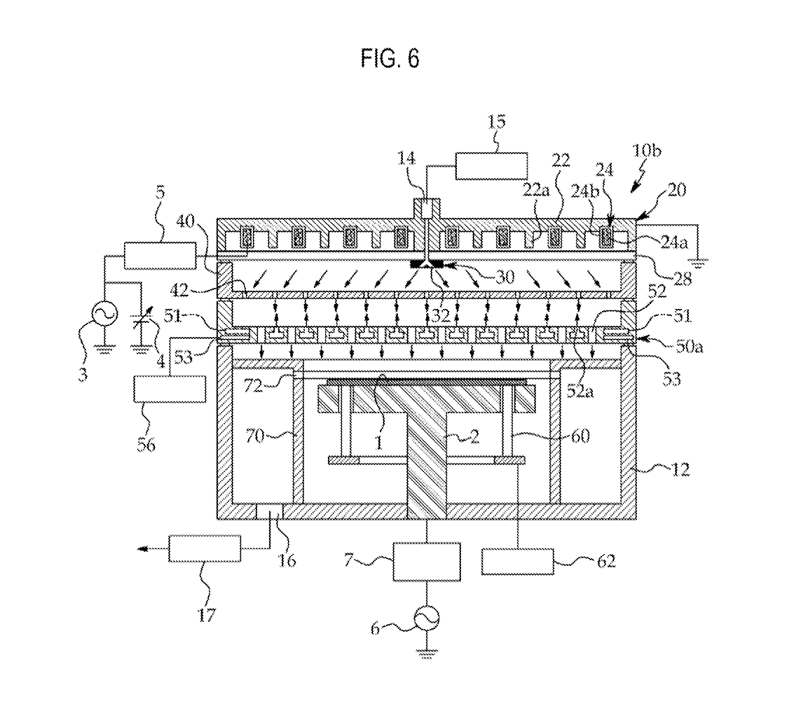

FIG. 6 is a view illustrating another embodiment of a first bas distribution baffle.

Referring to FIG. 6, in a first bas distribution baffle 50a of a plasma processing apparatus 10b, a vaporized gas injection hole 54a is disposed on a top of a first gas distribution baffle 50a. Therefore, a vaporized gas is injected above the first gas distribution baffle 50a through the vaporized gas injection hole 54a. Here, the vaporized gas may be directly supplied to a space between the first gas distribution baffle 50a and a second distribution baffle 40 using at least one nozzle. The vaporized gas supplied and the plasma distributed through the second gas distribution baffle 40 are mixed in a space (reactive area) between the first gas distribution baffle 50a and the second gas distribution baffle 40 to form reactive species. The reactive species are uniformly distributed toward a substrate to foe processed 1 through a through hole 52 of the first gas distribution hole 50a. Since the reactive species are formed in the space between the second gas distribution baffle 40 and the first gas distribution baffle 50a and then distributed toward the substrate to be processed 1, the plasma and vaporized gas may be reacted more efficiently, and the reactive species may be uniformly distributed toward the substrate to be processed 1 through the first through hole 52 of the first gas distribution baffle 50a.

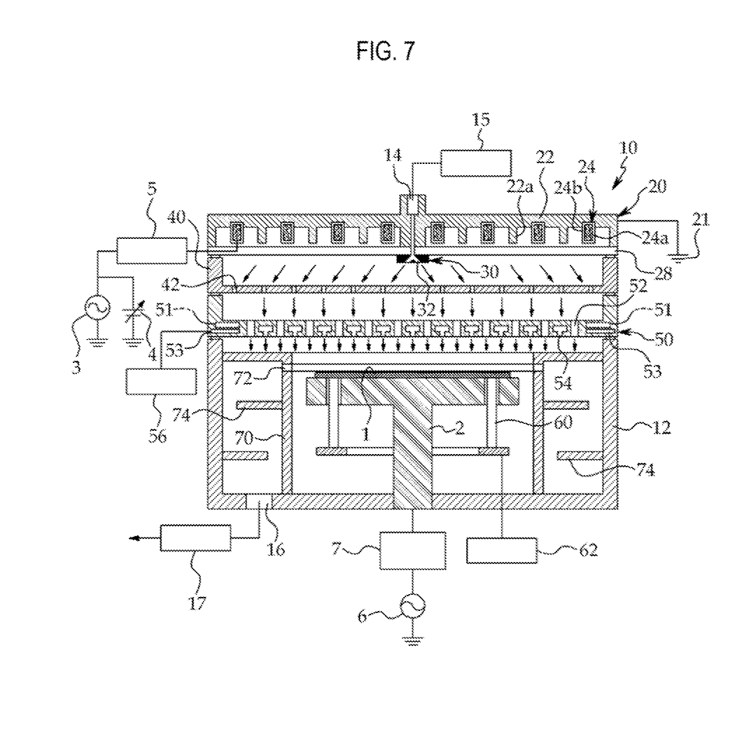

FIG. 7 is a view illustrating another embodiment of an exhaust baffle.

Referring to FIG. 7, an exhaust ring 70a may have a plurality of distribution plates 74 therein. The plurality of distribution plates 74 are a plurality of partition walls, which are alternately disposed on the inner wall of the exhaust ring 70a and the inner wall of the reactor body 12, and make the exhaust gas introduced into the exhaust ring 70a through the exhaust hole 72 discharged uniformly while passing through the partition plates disposed alternately.

It will be appreciated that the embodiments of the plasma apparatus for vapor phase etching and cleaning in accordance with the present invention are merely exemplary, and various modifications and equivalent other embodiments will be apparent to those skilled in the art.

Therefore, it will be clearly understood that the present invention is not limited to shapes mentioned in the detailed description. Accordingly, the true scope of technical protection of the present invention should be defined by the technical ideas of appended claims. Further, it should be understood that the present invention includes all the modifications, equivalences and substitutes within spirits and scopes of the present invention defined by appended claims.

What is claimed is:

1. A plasma processing apparatus for vapor phase etching and cleaning, comprising:
a reactor body configured to process a substrate to be processed;
a direct plasma generation area in the reactor body, into which a process gas is introduced and in which plasma is directly induced to disassociate the process gas;
a substrate processing area in the reactor body in which the substrate to be processed is processed by reactive species produced by reacting the disassociated process gas introduced from the direct plasma generation area with a vaporized gas introduced from the outside of the reactor body;
a plasma induction assembly configured to induce plasma in the direct plasma generation area; and
a gas distribution baffle, which is disposed between the direct plasma generation area and the substrate processing area and has a plurality of through holes that are perforated, through which the disassociated process gas is introduced from the direct plasma generation area to the substrate processing area.

2. The plasma processing apparatus of claim 1, wherein the gas distribution baffle includes a plurality of vaporised gas injection holes to inject vaporised gas introduced from the outside to the substrate processing area.

3. The plasma processing apparatus of claim 1, further comprising one or more gas injection nozzles, each of which directly injects the vaporized gas to the substrate processing area.

4. The plasma processing apparatus of claim 1, wherein the plasma induction assembly includes a first electrode and a second electrode that are capacitively coupled with each other.

5. The plasma processing apparatus of claim 4, wherein the plasma induction assembly includes a dielectric window that is mounted between the first and second electrodes and the direct plasma generation area.

6. The plasma processing apparatus of claim 1, wherein the gas distribution baffle includes a heater to control temperature.

7. The plasma processing apparatus of claim 1, wherein the plasma induction assembly includes a cooling channel.

8. The plasma processing apparatus of claim 1, wherein the vaporized gas is vaporized H₂O.

9. A plasma processing apparatus for vapor phase etching and cleaning, comprising:
a reactor body configured to process a substrate to be processed;
a direct plasma generation area in the reactor body, into which a process gas is introduced and in which plasma is directly induced to disassociate the process gas;
a reactive area in the reactor body, in which a disassociated process gas introduced from the direct plasma generation area is reacted with a vaporized gas introduced from the outside of the reactor body, thereby forming reactive species;
a substrate processing area in the reactor body, in which the substrate to be processed is processed by the reactive species introduced from the reactive area;
a plasma induction assembly configured to induce plasma into the direct plasma generation area;
a first gas distribution baffle that is disposed between the reactive area and the substrate processing area and that includes a plurality of first through holes that are perforated, through which the reactive species is introduced from the reactive area into the substrate processing area; and
a second gas distribution baffle that is disposed between the direct plasma generation area and the reactive area and that includes a second gas distribution baffle having a plurality of second through holes, through which the disassociated process gas is introduced from the direct plasma generation area into the reactive area.

10. The plasma processing apparatus of claim 9, wherein the first gas distribution baffle includes a plurality of vaporized gas injection holes to inject the vaporized gas introduced from the outside to the reactive area.

11. The plasma processing apparatus of claim 9, further comprising one or more gas injection nozzles, each of which directly injects the vaporized gas to the reactive area.

12. The plasma processing apparatus of claim 9, wherein the plasma induction assembly includes first and second electrodes that are capacitively coupled with each other.

13. The plasma processing apparatus of claim 12, wherein the plasma induction assembly includes a dielectric window that is mounted between the first and second electrodes and the direct plasma generation area.

14. The plasma processing apparatus of claim 9, wherein the first gas distribution baffle includes a heater to control temperature.

15. The plasma processing apparatus of claim 9, wherein the plasma induction assembly includes a cooling channel.

16. The plasma processing apparatus of claim 9, wherein the vaporized gas is vaporised H₂O.
